(19) United States
(12) Patent Application Publication
(10) Pub. No.: US 2025/0080074 A1
(43) Pub. Date: Mar. 6, 2025

(54) FILTER PRODUCTION METHOD AND FILTER

(71) Applicant: ANHUI ANUKI TECHNOLOGIES CO., LTD., Anhui (CN)

(72) Inventors: Wei CHENG, Anhui (CN); Chengjie ZUO, Anhui (CN); Peng WANG, Anhui (CN); Zheng WANG, Anhui (CN)

(21) Appl. No.: 18/022,490

(22) PCT Filed: Oct. 26, 2021
(86) PCT No.: PCT/CN2021/126502

§ 371 Date: Feb. 21, 2023

(51) Int. Cl. H03H 3/02; H05K 3/00; H05K 3/18

(52) U.S. Cl. CPC H03H 3/02; H05K 3/0047; H05K 3/18

(57) ABSTRACT

Disclosed are a filter production method and a filter, which relate to the technical field of wireless communication. In the above, the filter production method includes: providing a substrate structure; producing and forming a line structure on at least one side of the substrate structure, wherein the line structure includes at least one line layer, and at least one of the line layers has at least one inductor element; and producing and forming a capacitor structure and/or a resonator structure on the side of the at least one line layer close to the substrate structure and/or away from the substrate structure, wherein the capacitor structure includes at least one capacitor element, and the resonator structure includes at least one acoustic resonator. On the basis of the above method, the problem of relatively large integrated size existing in filters produced according to the prior art can be improved.

### TECHNICAL FIELD

The present disclosure relates to the technical field of wireless communication, and particularly to a filter production method and a filter.

### BACKGROUND ART

In the wireless radio frequency communication technology, the performance of radio frequency communication devices directly influences the quality of wireless communication. In the above, in the radio frequency communication devices, in order to effectively process received signals and signals to be sent, it is required to provide a corresponding filter structure.

It is discovered by the inventors in research that in existing filter structure production technology, filter structure has the problem of relatively large size due to the relatively low integration level of the filter structure, which restrains the application range thereof.

### SUMMARY

In view of this, an object of the present disclosure is to provide a filter production method and a filter, so as to improve the problem of relatively large integrated size existing in filters produced in the prior art.

To achieve the above-mentioned object, following technical solution is employed in an embodiment of the present disclosure:

A filter production method, comprising:
providing a substrate structure;
producing and forming a line structure on at least one side of the substrate structure, wherein the line structure comprises at least one line layer, and at least one of the line layers has at least one inductor element; and
producing and forming a capacitor structure and/or a resonator structure on the side of at least one of the line layers close to the substrate structure and/or away from the substrate structure, wherein the capacitor structure comprises at least one capacitor element, and the resonator structure comprises at least one acoustic resonator;
wherein the substrate structure and the line structure as well as the capacitor structure and/or the resonator structure form a lamellar stack structure, and the inductor element and the capacitor element and/or the acoustic resonator are in electrical connection with each other, so as to form a filter circuit.

In a preferred option of the embodiment of the present disclosure, in the above-mentioned filter production method, the step of producing and forming a capacitor structure and/or a resonator structure on the side of at least one of the line layers close to the substrate structure and/or away from the substrate structure comprises:
producing and forming at least one capacitor element and/or at least one acoustic resonator on the basis of at least one external surface of the substrate structure.

In a preferred option of the embodiment of the present disclosure, in the above-mentioned filter production method, the step of producing and forming a capacitor structure and/or a resonator structure on the side of at least one of the line layers close to the substrate structure and/or away from the substrate structure comprises:
producing and forming at least one capacitor element and/or at least one acoustic resonator in at least one inwardly concave area of the substrate structure.

In a preferred option of the embodiment of the present disclosure, in the above-mentioned filter production method, the step of producing and forming at least one capacitor element and/or at least one acoustic resonator in at least one inwardly concave area of the substrate structure comprises:
producing and forming at least one inwardly concave area on at least one external surface of the substrate structure;
producing and forming a substrate layer on the basis of the external surface of the substrate structure in each of the inwardly concave areas; and
producing and forming at least one capacitor element and/or at least one acoustic resonator on the basis of the surface on each of the substrate layers not contacting with the substrate structure.

In a preferred option of the embodiment of the present disclosure, in the above-mentioned filter production method, the step of producing and forming a substrate layer on the basis of the external surface of the substrate structure comprises:
producing a substrate layer of a material differing from that of the substrate structure on the basis on the external surface of the substrate structure, wherein the substrate layer is configured for producing and forming an acoustic resonator.

In a preferred option of the embodiment of the present disclosure, in the above-mentioned filter production method, the step of producing and forming a capacitor structure or a resonator structure on the side of the at least one layer of the inductor element close to the substrate structure and/or away from the substrate structure comprises:
producing and forming, after the production and formation of one of the line layers, at least one capacitor element and/or at least one acoustic resonator on the basis of a dielectric isolation layer formed on the line layer.

In a preferred option of the embodiment of the present disclosure, in the above-mentioned filter production method, the step of producing and forming a line structure on at least one side of the substrate structure comprises:
producing and forming, after the production and formation of a layer of a lamellar structure having a capacitor element and/or an acoustic resonator, a line layer on the basis of a dielectric isolation layer formed on the lamellar structure.

In a preferred option of the embodiment of the present disclosure, in the above-mentioned filter production method, the step of producing and forming a line structure on at least one side of the substrate structure comprises:
producing and forming at least one line layer on the basis of at least one external surface of the substrate structure.

In a preferred option of the embodiment of the present disclosure, in the above-mentioned filter production method, the step of producing and forming at least one line layer on the basis of at least one external surface of the substrate structure comprises:
performing a window etching operation on a metal foil on the substrate structure;
performing a drilling operation on the basis of the surface of the window-etched metal foil away from the substrate structure, so as to form a connecting via hole penetrating the metal foil and the substrate structure;
performing a metal electroplating operation on the basis of the surface of the drilled metal foil away from the substrate structure, so as to form a metal layer covering the metal foil and filling the connecting via hole; and
performing graphics etching operations on the surface of the metal layer away from the metal foil, so as to form a line layer.

Based on the foregoing contents, an embodiment of the present disclosure further provides a filter, which is produced and formed on the basis of the above-mentioned filter production method.

As for the filter production method and the filter provided in the present disclosure, a filter comprising an inductor element, a capacitor element and/or an acoustic resonator can be formed by producing and forming, on at least one side of the provided substrate structure, a line structure comprising at least one line layer and producing and forming, on at least one side of the at least one line layer, a capacitor structure and/or a resonator structure. In this way, since the line structure, the capacitor structure, and the resonator structure actually form a stack structure, the integration level of formed filter can be increased, such that the filter may have a smaller integrated size, so as to improve the problem of relatively large integrated size existing in filter structure produced in the prior art (for example, the respective elements of the filter structure are produced and formed separately and then packaged as a whole), and further improve the application range of the produced filter. For example, a smaller volume can facilitate the arrangement in various application environments, such that it has an extremely high practical value and can be widely applied.

In order to make the above-mentioned objects, features, and advantages of the present disclosure more evident and easier to understand, preferred embodiments will be specifically exemplified below and described in detail with reference to the accompanying drawings as follows.

### BRIEF DESCRIPTION OF DRAWINGS

FIG. 1 is a schematic flow diagram of a filter production method provided in an embodiment of the present disclosure.

FIG. 2 is a schematic structural diagram of a filter provided in an embodiment of the present disclosure.

FIG. 3 is a schematic diagram of a production location of an inductor element provided in an embodiment of the present disclosure.

FIG. 4 is a schematic diagram of another production location of the inductor element provided in an embodiment of the present disclosure.

FIG. 5 is a schematic flow diagram of sub-steps contained in step S120 in FIG. 1.

FIG. 6 is a schematic diagram showing the effect of production of line layer provided in an embodiment of the present disclosure.

FIG. 7 is a schematic diagram of a first production location of a capacitor element provided in an embodiment of the present disclosure.

FIG. 8 is a schematic diagram of a second production location of the capacitor element provided in an embodiment of the present disclosure.

FIG. 9 is a schematic diagram of a third production location of a capacitor element provided in an embodiment of the present disclosure.

FIG. 10 is a schematic flow diagram of sub-steps contained in step S130 in FIG. 1.

FIG. 11 is a schematic diagram of effect of capacitor element production provided in an embodiment of the present disclosure.

FIG. 12 is a schematic circuit diagram of a duplexer provided in an embodiment of the present disclosure.

Reference signs: 10—duplexer; 12—receiving filter; 14—sending filter; 100—filter; 110—substrate structure; 120—line structure; 121—inductor element; 130—capacitor structure; 131—capacitor element; 140—resonator structure; 141—acoustic resonator; and 150—dielectric isolation layer.

### DETAILED DESCRIPTION OF EMBODIMENTS

In order to make the objects, the technical solutions, and the advantages of the embodiments of the present disclosure clearer, the technical solutions in the embodiments of the present disclosure will be clearly and comprehensively described below with reference to the accompanying drawings in the embodiments of the present disclosure. Clearly, the described embodiments are merely some of the embodiments of the present disclosure, but not all the embodiments thereof. Generally, the assemblies of the embodiments of the present disclosure that are described and shown here in the accompanying drawings may be arranged and designed according to various configurations.

Thus, following detailed description of the embodiments of the present disclosure that are provided in the drawings merely represents selected embodiments of the present disclosure, rather than being intended to limit the scope of the present disclosure for which protection is sought. All other embodiments, which could be obtained by a person ordinarily skilled in the art on the basis of the embodiments in the present disclosure without creative effects, shall fall within the scope of protection of the present disclosure.

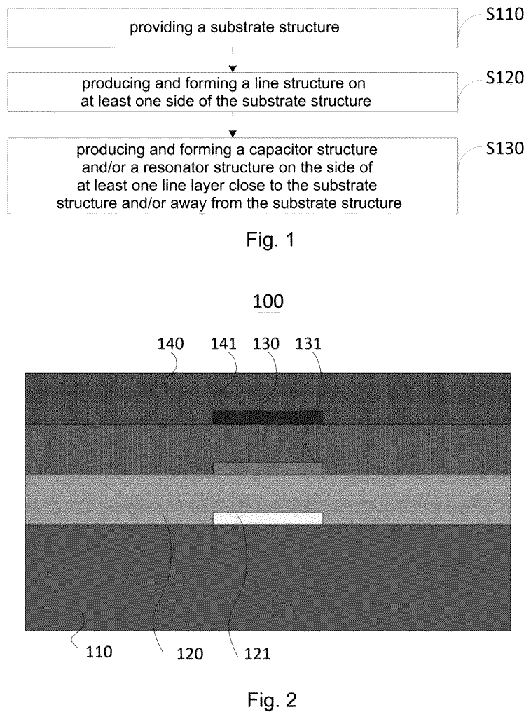

As shown in FIGS. 1 and 2, an embodiment of the present disclosure provides a filter production method for producing and forming a filter 100. In the above, the filter production method can comprise step S110, step S120, and step S130, and specific contents thereof are described below.

Step S110: providing a substrate structure 110.

In the present embodiment, a substrate structure 110 can firstly be provided, such that other structures (e.g., a line structure 120, a capacitor structure 130, a resonator structure 140 and the like) can be produced and formed on the basis of this substrate structure 110.

Step S120: producing and forming a line structure 120 on at least one side of the substrate structure 110.

In the present embodiment, after providing the substrate structure 110 based on step S110, a line structure 120 can be produced and formed on at least one side of the substrate structure 110.

In the above, the line structure 120 may comprise at least one line layer, and at least one of the line layers has at least one inductor element 121, hereby obtaining at least one inductor element 121.

Step S130: producing and forming a capacitor structure 130 and/or a resonator structure 140 on the side of at least one of the line layers close to the substrate structure 110 and/or away from the substrate structure 110.

In the present embodiment, after providing the substrate structure 110 based on step S110, a capacitor structure 130 and/or a resonator structure 140 can further be produced and formed, and the capacitor structure 130 and/or the resonator structure 140 can be located on the side of the at least one of the line layers close to the substrate structure 110 and/or away from the substrate structure 110.

In the above, the capacitor structure 130 may comprise at least one capacitor element 131, and the resonator structure 140 may comprise at least one acoustic resonator 141. In this way, at least one capacitor element 131 and/or at least one acoustic resonator 141 can be formed.

Moreover, the substrate structure 110 and the line structure 120 as well as the capacitor structure 130 and/or the resonator structure 140 can form a lamellar stack structure, and the inductor element 121 and the capacitor element 131 and/or the acoustic resonator 141 can be in electrical connection with each other, so as to form a filter circuit.

Based on the above method, a filter 100 stacked lamellarly (at least one from the inductor element 121 as well as the capacitor element 131 and the acoustic resonator 141 contained therein forms a stacking relationship) can be formed practically on the provided substrate structure 110, that is to say, the substrate structure 110, the line structure 120, the capacitor structure 130, and the resonator structure 140 practically form a stacking structural relationship. Therefore, the integration level of the formed filter 100 can be improved, so as to improve the problem of relatively large integrated size existing in filter structure produced on the basis of the prior art.

In a first aspect, it shall be clarified for step S110 that the specific mode for providing the substrate structure 110 is not limited and can be selected according to practical application requirements.

As an example, in an alternative example, it is possible to directly provide a material structure, such as silicon, glass, quartz, sapphire, lithium niobate, lithium tantalate or the like, as the substrate structure 110.

As another example, in another alternative example, it is also possible to provide a base plate material as the substrate structure 110. In the above, considering that in the base plate material, there is generally a layer of copper foil on both surfaces of the base plate, thereby it is possible to remove the copper foil and form a substrate structure 110, and it is also possible to produce a capacitor element 131 or an inductor element 121 or the like by directly using this copper foil.

In a second aspect, it shall be clarified for step S120 that the specific mode for producing and forming the line structure 120 is not limited and can also be selected according to practical application requirements.

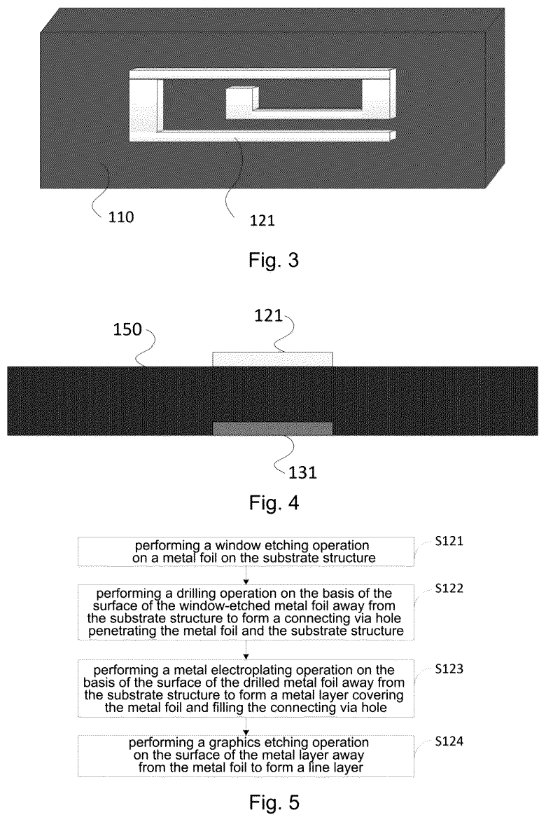

As an example, in an alternative example, with reference to FIG. 3, at least one line layer can be produced and formed on the basis of at least one external surface of the substrate structure 110.

In other words, it is possible to produce and form one line layer or multi-stacked line layers on the basis of one external surface of the substrate structure 110. It is also possible to respectively produce and form one line layer or multiple line layers on the basis of two opposite external surfaces of the substrate, that is to say, one line layer or multi-stacked line layers can be produced and formed on one of the external surfaces, and one line layer or multi-stacked line layers can also be produced and formed on the other external surface.

As another example, in another alternative example, with reference to FIG. 4, it is possible that produce and form, after the production and formation of a layer of a lamellar structure having a capacitor element 131 and/or an acoustic resonator 141, a line layer on the basis of a dielectric isolation layer 150 formed on the lamellar structure.

In other words, in a specific application example, it is possible that after the production and formation of a layer of a lamellar structure having a capacitor element 131, a dielectric isolation layer 150 is produced and formed on this lamellar structure, and then at least one line layer is produced and formed on the basis of this dielectric isolation layer 150.

In another specific application example, it is also possible that after the production and formation of a layer of a lamellar structure having an acoustic resonator 141, a dielectric isolation layer 150 is produced and formed on this lamellar structure, and then at least one line layer is produced and formed on the basis of this dielectric isolation layer 150.

In another specific application example, it is further possible that after the production and formation of a layer of a first lamellar structure having a capacitor element 131 on one side of the substrate structure 110 and the production and formation of a layer of a second lamellar structure having an acoustic resonator 141 on the other side of the substrate structure 110, a first dielectric isolation layer and a second dielectric isolation layer are produced and formed respectively on this first lamellar structure and this second lamellar structure, and then at least one line layer is produced and formed respectively on the basis of the first dielectric isolation layer and the second dielectric isolation layer.

Optionally, in the above step, the specific mode for producing and forming the line layer is not limited and can be selected according to practical application requirements.

As an example, in an alternative example, when producing a line layer on the basis of the dielectric isolation layer 150, it is possible to firstly form a metal conducting layer on this dielectric isolation layer 150, and then drill on the basis of the surface of this metal conducting layer away from the dielectric isolation layer 150 so as to penetrate this metal conducting layer and the dielectric isolation layer 150. In this way, another layer of metal conducting layer is further formed on the basis of the surface of the metal conducting layer away from the dielectric isolation layer 150, such that the thickness of the metal conducting layers is increased; and the through hole formed by drilling is filled, such that an electrical connection can be realized between this metal conducting layer and the capacitor element 131 or the acoustic resonator 141 on the surface of the dielectric isolation layer 150 away from the metal conducting layer.

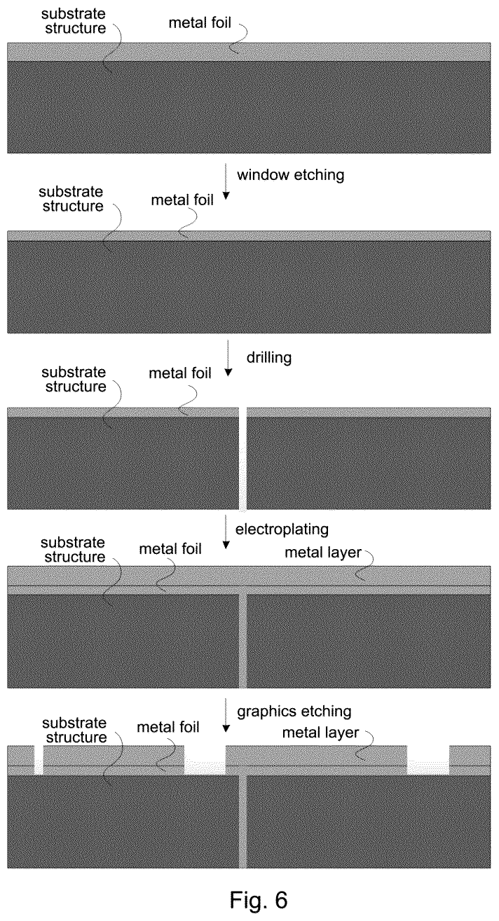

As another example, in another alternative example, with reference to FIGS. 5 and 6, when a line layer is produced on the basis of the substrate structure 110 and this substrate structure 110 has a metal foil thereon (e.g., using a base plate material for providing the substrate structure 110), step S120 can comprise step S121, step S122, step S123, and step S124, and specific contents thereof are described below.

Step S121: performing a window etching operation on a metal foil on the substrate structure 110.

In the present embodiment, when a base plate material is used in step S110 for providing the substrate structure 110, the metal foil on this substrate structure 110 can firstly be subjected to a window etching operation. In this way, the thickness of the metal foil can be reduced so as to facilitate subsequent drilling operation.

Step S122: performing drilling operations on the basis of the surface of the window-etched metal foil away from the substrate structure 110, so as to form a connecting via hole penetrating the metal foil and the substrate structure 110.

In the present embodiment, after that the metal foil has been subjected to a window etching operation on the basis of step S121, a drilling operation (e.g., laser drilling) can be performed on the basis of the surface of the metal foil away from the substrate structure 110, so as to penetrate the metal foil and the substrate structure 110. In this way, a connecting via hole penetrating the metal foil and the substrate structure 110 can be formed.

Step S123: performing metal electroplating operations on the basis of the surface of the drilled metal foil away from the substrate structure 110, so as to form a metal layer covering the metal foil and filling the connecting via hole.

In the present embodiment, after that the metal foil has been subjected to the drilling operation on the basis of step S122, a metal electroplating operation can be performed on the basis of the surface of the metal foil away from the substrate structure 110. In this way, a metal layer covering the metal foil and filling the connecting via hole can be formed, such that the surface of the substrate structure 110 away from the metal foil can be in electrical connection with the metal foil.

Step S124: performing a graphics etching operation on the surface of the metal layer away from the metal foil to form a line layer.

In the present embodiment, after that the metal foil has been subjected to the metal electroplating operation on the basis of step S123 to form a metal layer, the graphics (pattern) etching operation can be performed on the basis of the surface of the metal layer away from the metal foil. In this way, one line layer can be formed.

It could be understood that the formation of a line layer in step S124 may refer to a lamellar structure with an inductor element 121, or refer to a lamellar structure without an inductor element 121, for example, a conductive connecting line for tandem connection of different elements (such as between inductor elements 121, between an inductor element 121 and a capacitor element 131, between an inductor element 121 and an acoustic resonator 141, between capacitor elements 131, between acoustic resonators 141 or the like in other lamellar structures).

Moreover, after the production and formation of a line layer on the basis of step S124, optical detection of graphics, brown oxidation treatment, dielectric laminating treatment and the like may also be performed.

In the above, optical detection of graphics may refer to the detection of graphics of the produced and formed line layer (such as graphics of the inductor element 121), so as to determine whether this line layer meets the requirements. Brown oxidation treatment may refer to the cleaning process of residual film and contaminants on the produced and formed line layer caused by etching and the deposition of a layer of organic metal film on the surface of the line layer, which improves the adhesive capacity of the line layer (e.g., the capacity of adhering to a dielectric isolation layer 150 to be formed by press fitting). The dielectric layer treatment may refer to the formation of one dielectric isolation layer 150 on the produced and formed line layer. Moreover, for the dielectric isolation layer 150, if the dielectric isolation layer 150 is not the outermost layer of the filter 100, one isolation layer can be formed by way of press fitting on the line layer (or may also be formed on the produced and formed capacitor element 131 or acoustic resonator 141); if the dielectric isolation layer 150 is the outermost layer of the filter 100, one solder mask layer can be formed on the line layer (or may also be formed on the produced and formed capacitor element 131 or acoustic resonator 141).

In the above, same material can be used for the above isolation layer and for the solder mask layer, for example, a rubber material can be used for the both; however, the hardness of the isolation layer can be different from that of the solder mask layer, for example, the hardness of the isolation layer can be smaller than the hardness of the solder mask layer.

It could be understood that when producing and forming the solder mask layer, pins for the line layer, the capacitor element 131 or the acoustic resonator 141 should be exposed, and for protecting the pins, the pins can be subjected to gold plating treatment.

In a second aspect, it shall be clarified for step S130 that the specific mode for producing and forming the capacitor structure 130 and/or the resonator structure 140 is not limited and can be selected according to practical application requirements.

As an example, in an alternative example, it is possible to only produce and form a capacitor structure 130. As another example, in another alternative example, it is possible to only produce and form a resonator structure 140. As yet another example, in another alternative example, it is possible to produce and form a capacitor structure 130 and a resonator structure 140.

In the above, the production and formation of the capacitor structure 130 and/or the resonator structure 140 actually refers to the production and formation of at least one capacitor element 131 and/or at least one acoustic resonator 141.

Optionally, the specific mode for producing and forming at least one capacitor element 131 and/or at least one acoustic resonator 141 is not limited and can be selected according to practical application requirements.

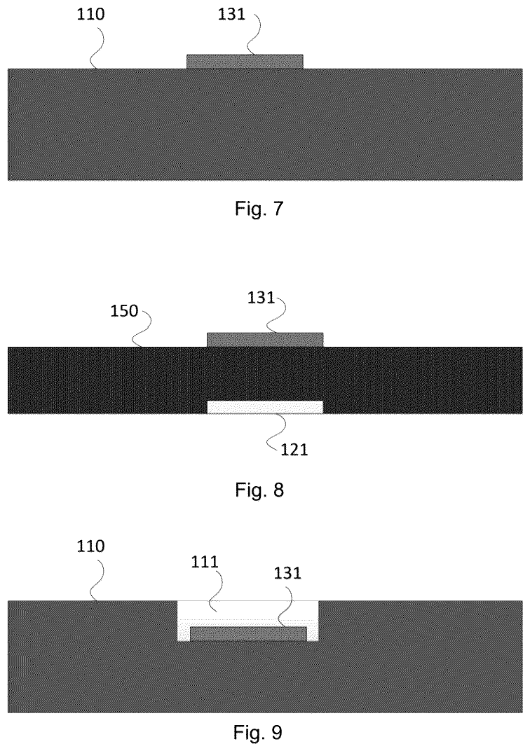

As an example, in an alternative example, with reference to FIG. 7, in order to ensure that the produced and formed capacitor element 131 and/or acoustic resonator 141 has relatively high performance, step S130 may comprise following sub-step:

It is possible to produce and form at least one capacitor element 131 and/or at least one acoustic resonator 141 on the basis of at least one external surface of the substrate structure 110.

In other words, after that the substrate structure 110 is provided on the basis of step S110, at least one capacitor element 131 can be produced and formed and/or at least one acoustic resonator 141 can be produced and formed on a surface of the substrate structure 110.

In detail, in a specific application example, at least one capacitor element 131 or at least one acoustic resonator 141 can be produced and formed on one external surface of the substrate structure 110. In another specific application example, it is also possible to respectively produce and form at least one capacitor element 131 on both external surfaces of the substrate structure 110. In another specific application example, it is further possible to produce and form at least one capacitor element 131 on one external surface of the substrate structure 110, and to produce and form at least one acoustic resonator 141 on the other external surface of the substrate structure 110. Moreover, in another specific application example, it is further possible to respectively produce and form at least one acoustic resonator 141 on both external surfaces of the substrate structure 110.

As another example, in another alternative example, with reference to FIG. 8, on the basis of certain process requirements, for example, relatively high press-fitting process accuracy of the dielectric isolation layer 150, step S130 may also comprise following sub-step:

It is possible that after the production and formation of one of the line layers, at least one capacitor element 131 is produced and formed and/or at least one acoustic resonator 141 is produced and formed on the basis of the dielectric isolation layer 150 formed on the line layer.

In other words, after the production and formation of one of the line layers on the basis of step S120, a dielectric isolation layer 150 can be firstly produced and formed on the line layer, and then, at least one capacitor element 131 is produced and formed and/or at least one acoustic resonator 141 is produced and formed on the basis of the surface of the dielectric isolation layer 150 away from the line layer.

In detail, in a specific application example, it is possible to produce and form at least one capacitor element 131 on the surface of the dielectric isolation layer 150 away from the line layer. In another alternative example, it is possible to produce and form at least one acoustic resonator 141 on the surface of the dielectric isolation layer 150 away from the line layer. In another specific application example, it is also possible to produce and form at least one capacitor element 131 on the surface of the dielectric isolation layer 150 away from the line layer, then also produce one dielectric isolation layer 150, and produce and form at least one acoustic resonator 141 on the surface of the dielectric isolation layer 150 away from the capacitor element 131. Moreover, in another specific application example, it is further possible to produce and form at least one acoustic resonator 141 on the surface of the dielectric isolation layer 150 away from the line layer, then also produce one dielectric isolation layer 150, and produce and form at least one capacitor element 131 on the surface of the dielectric isolation layer 150 away from the acoustic resonator 141.

As yet another example, in another alternative example, in order to improve the integration level of the produced and formed filter 100 to make the integrated size smaller, step S130 can comprise following sub-step:

It is possible to produce and form at least one capacitor element 131 and/or at least one acoustic resonator 141 in at least one inwardly concave area of the substrate structure 110.

In other words, after that the substrate structure 110 is provided on the basis of step S110, at least one capacitor element 131 and/or at least one acoustic resonator 141 can be produced and formed in at least one inwardly concave area of the substrate structure 110.

In detail, in a specific application example, at least one capacitor element 131 can be produced and formed in at least one inwardly concave area of the substrate structure 110. In another specific application example, it is also possible to produce and form at least one acoustic resonator 141 in at least one inwardly concave area of the substrate structure 110. In another alternative example, it is further possible to respectively produce and form at least one capacitor element 131 and at least one acoustic resonator 141 in multiple inwardly concave areas of the substrate structure 110.

Optionally, the specific mode for producing and forming at least one capacitor element 131 and/or at least one acoustic resonator 141 is not limited and can also be selected according to practical application requirements.

As an example, in an alternative example, in order to reduce the complexity of the process, with reference to FIG. 9, step S130 can comprise following sub-steps:

Firstly, at least one inwardly concave area can be produced and formed on at least one external surface of the substrate structure 110; secondly, at least one capacitor element 131 and/or at least one acoustic resonator 141 can be produced and formed on the basis of the external surface of the substrate structure 110 in the inwardly concave area.

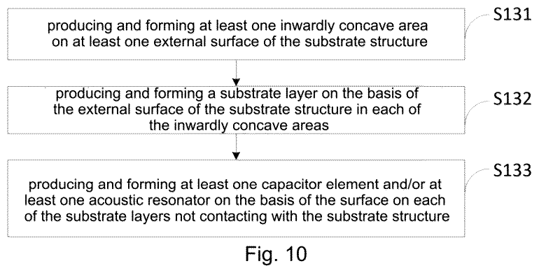

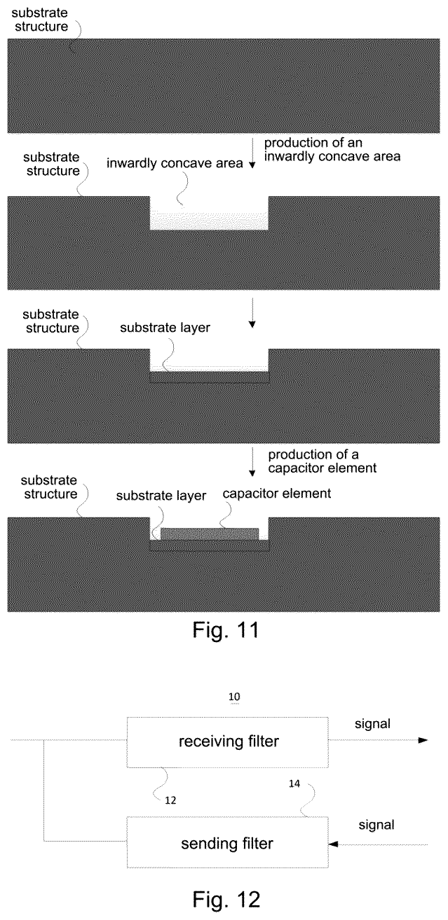

As another example, in an alternative example, in order to ensure that the produced and formed capacitor element 131 and/or acoustic resonator 141 has good performance, with reference to FIGS. 10 and 11, step S130 may also comprise step S131, step S132, and step S133, and specific contents thereof are described below.

Step S131: producing and forming at least one inwardly concave area on at least one external surface of the substrate structure 110.

In the present embodiment, after providing the substrate structure 110 based on step S110, at least one inwardly concave area can be produced and formed on the basis of at least one external surface of the substrate structure 110.

Step S132: producing and forming a substrate layer on the basis of the external surface of the substrate structure 110 in each of the inwardly concave areas.

In the present embodiment, after the production and formation of the at least one inwardly concave area on the basis of step S131, a substrate layer can be produced and formed on the basis of the external surface of the substrate structure 110 in each of the inwardly concave areas. In this way, the surface for producing the capacitor element 131 and/or the acoustic resonator 141 can be made to be relatively even, which may further ensure that the capacitor element 131 and/or the acoustic resonator 141 can have good performance, while the production is facilitated.

Step S133: producing and forming at least one capacitor element 131 and/or at least one acoustic resonator 141 on the basis of the surface on each of the substrate layers not contacting with the substrate structure 110.

In the present embodiment, after that the substrate layer is produced and formed on the basis of step S132, for the substrate layer of each of the inwardly concave areas, a capacitor element 131 or an acoustic resonator 141 can be produced and formed on the basis of the surface on the substrate layer not contacting with the substrate structure 110. In this way, at least one capacitor element 131 and/or at least one acoustic resonator 141 can be produced and formed.

Optionally, in step S131, it is possible to produce and form at least one inwardly concave area on one external surface of the substrate structure 110, and it is also possible to respectively produce and form at least one inwardly concave area on two opposite external surfaces of the substrate structure 110.

Moreover, the specific mode for producing and forming the inwardly concave area is not limited and can also be selected according to practical application requirements. As an example, in an alternative example, it is possible to form the inwardly concave area by way of etching or the like.

Optionally, in step S132, the specific mode for producing and forming the substrate layer is not limited and can also be selected according to practical application requirements.

As an example, in an alternative example, the substrate layer can be produced and formed on the basis of the same material as that of the substrate structure 110. In other words, the material of the substrate layer can be the same as the material of the substrate structure 110.

As another example, in another alternative example, it is discovered by the inventors of the present disclosure in research that materials suitable for producing and forming the concave area may be unsuitable for producing an acoustic resonator 141, thus, the substrate layer can be produced and formed on the basis of a material different from that of the substrate structure 110. In other words, the material of the substrate layer may be different from the material of the substrate structure 110.

In detail, in a specific application example, the material of the substrate structure 110 may be a base plate material or a PCB (Printed Circuit Board) material, and the material of the substrate layer may be silicon, lithium niobate, or lithium tantalate.

It could be understood that in the above examples, the specific mode for producing and forming a capacitor element 131 and/or an acoustic resonator 141 is not limited and can be selected according to practical application requirements.

On the one hand, the capacitor element 131 may be refer to a plate (MIM, Metal Insulator Metal) capacitor, or an integrated capacitor, that is to say, at least one capacitor element 131 is integrated as a whole, hereby forming an integrated capacitor chip.

On the other hand, the acoustic resonator 141 may be either a single resonator, or an integrated resonator, that is to say, at least one acoustic resonator 141 is integrated as a whole, hereby forming an integrated resonator chip.

In the above, when producing a plate capacitor, the specific mode may be as follows: firstly, a first metal electrode plate can be produced and formed by way of electroplating or the like (if a base plate material is used as the substrate structure 110, and the plate capacitor is produced on an external surface of the substrate structure 110, the first metal electrode plate may also be formed by performing graphics etching on the basis of a copper foil contained in the base plate material); secondly, a dielectric layer (which may be an electrolyte film, such as tantalum oxide, silicon oxide, silicon nitride or the like) can be produced and formed on the basis of this first metal electrode plate by way of PECVD (Plasma Enhanced Chemical Vapor Deposition) or the like; then, a second metal electrode plate can be produced and formed on the basis of this dielectric layer by way of electroplating or the like.

Moreover, the specific types of the acoustic resonator 141 may include, but are not limited to, surface acoustic wave (SAW) resonators, solidly mounted resonators (SMR), film bulk acoustic resonators (FBAR) and the like.

It could be understood that in the above examples, the specific sequential order of step S120 and step S130 is not limited and can be selected according to practical application requirements.

As an example, in an alternative example, step S120 can be executed firstly to form a line structure 120, and step S130 can then be executed to form a capacitor structure 130 and/or a resonator structure 140.

As another example, in another alternative example, it is also possible to firstly execute step S130 to form a capacitor structure 130 and/or a resonator structure 140, and then execute step S120 to form a line structure 120.

As yet another example, in another alternative example, it is further possible to alternately execute step S120 and step S130, for example, to execute step S120 once to form one line layer, then execute step S130 once to form at least one capacitor element 131 or at least one acoustic resonator 141, and then execute step S120 once to form one line layer again.

Further referring to FIG. 2, an embodiment of the present disclosure further provides a filter 100. In the above, the filter 100 can be produced and formed on the basis of the above-mentioned filter production method.

In other words, the filter 100 can comprise a substrate structure 110 and an inductor structure, and further comprise a capacitor structure 130 and/or a resonator structure 140. In the above, the inductor structure comprises at least one line layer, and at least one of the line layers has at least one inductor element 121. The capacitor structure 130 can comprise at least one capacitor element 131, the resonator structure 140 can comprise at least one acoustic resonator 141, and the inductor element 121 and the capacitor element 131 and/or the acoustic resonator 141 can be in electrical connection with each other, so as to form a filter circuit.

In this way, the substrate structure 110 and the inductor structure as well as one of the capacitor structure 130 and the resonator structure 140 actually can form a lamellar-stacked structural relationship, such that the constituted filter 100 can have a higher integration level, that is, the integrated size is smaller.

In a first aspect, it shall be clarified for the substrate structure 110 that the specific structure of the substrate structure 110 is not limited and can be selected according to practical application requirements.

As an example, in an alternative example, based on the requirements for electrical connection, the substrate structure 110 can have a connecting via hole thereon penetrating the substrate structure 110, and this connecting via hole is filled with a metal material for electrically connecting two opposite surfaces of the substrate structure 110, for example, connecting different elements (e.g., the inductor element 121, the capacitor element 131, and the acoustic resonator 141) on both surfaces of the substrate structure 110.

In a second aspect, it shall be clarified for the line structure 120 that the specific structure of the line structure 120 is not limited and can be selected according to practical application requirements.

As an example, in an alternative example, a dielectric isolation layer 150 can be formed on a layer of produced and formed lamellar structure having a capacitor element 131 and/or an acoustic resonator 141, and a line layer can be produced and formed on the surface of the dielectric isolation layer 150 away from the lamellar structure.

As another example, in another alternative example, at least one line layer can be produced and formed on at least one external surface of the substrate structure 110.

In a third aspect, it shall be clarified for the capacitor structure 130 and/or the resonator structure 140 that the specific structure of the capacitor structure 130 and/or the resonator structure 140 is not limited and can be selected according to practical application requirements.

As an example, in an alternative example, at least one capacitor element 131 can be produced and formed and/or at least one acoustic resonator 141 can be produced and formed on at least one external surface of the substrate structure 110.

As another example, in another alternative example, a dielectric isolation layer 150 can be formed on one of the produced and formed line layers, and at least one capacitor element 131 and/or at least one acoustic resonator 141 can be produced and formed on the surface of the dielectric isolation layer 150 away from the line layer.

As yet another example, in another alternative example, the substrate structure 110 can have at least one inwardly concave area, and at least one capacitor element 131 and/or at least one acoustic resonator 141 can be produced and formed in the at least one inwardly concave area.

In detail, in a specific application example, a substrate layer can be produced and formed on the external surface of the substrate structure 110 in each of the inwardly concave areas. In this way, at least one capacitor element 131 and/or at least one acoustic resonator 141 can be produced and formed on the surface on each of the substrate layers not contacting with the substrate structure 110.

In other words, the capacitor element 131 and/or the acoustic resonator 141 can be respectively produced and formed in the inwardly concave areas of the substrate structure 110 through the substrate layer.

In the above, the material type of the substrate layer is not limited. As an example, in an alternative example, the material for producing a substrate layer having the acoustic resonator 141 may be different from the material of the substrate structure 110.

It shall be clarified that when the line layer is multi-layer, the multiple line layers may be spaced only by a dielectric isolation layer 150, and may also be spaced by a dielectric isolation layer 150 and another lamellar structure, e.g., a capacitor structure 130 and/or a resonator structure 140.

Moreover, when there are multiple capacitor elements 131 and they are respectively located in different lamellar structures; different capacitor elements 131 may be spaced only by a dielectric isolation layer 150, or may also be spaced by a dielectric isolation layer 150 and another lamellar structure, e.g., a line layer and/or a resonator structure 140.

Furthermore, when there are multiple acoustic resonators 141 and they are respectively located in different lamellar structures; different acoustic resonators 141 may be spaced only by a dielectric isolation layer 150, or may also be spaced by a dielectric isolation layer 150 and another lamellar structure, e.g., a capacitor structure 130 and/or a resonator structure 140.

It could be understood that for the specific structure of the filter 100, reference can be made to the explanations of the filter production method described in the preceding contents, and no repetitive description will be made in detail here.

With reference to FIG. 12, an embodiment of the present disclosure further provides a duplexer 10. In the above, this duplexer 10 can comprise a receiving filter 12 and a sending filter 14, and at least one of the receiving filter 12 and the sending filter 14 belongs to the above filter 100.

In detail, the receiving filter 12 can be configured for processing received signals (e.g., radio frequency signals), and the sending filter 14 can be configured for processing signals to be sent.

In summary, as for the filter production method and the filter 100 provided in the present disclosure, a filter 100 comprising an inductor element 121, a capacitor element 131 and/or an acoustic resonator 141 can be formed by producing and forming a line structure 120 comprising at least one line layer on at least one side of the provided substrate structure 110 and producing and forming a capacitor structure 130 and/or a resonator structure 140 on at least one side of the at least one line layer. In this way, since the line structure 120, the capacitor structure 130, and the resonator structure 140 actually form a stack structure, the integration level of the formed filter 100 can be increased, such that the filter 100 may have a smaller integrated size, so as to improve the problem of relatively large integrated size existing in filter structure produced on the basis of the prior art (for example, the respective elements of the filter structure are produced and formed separately and then packaged as a whole), and to thereby improve the application range of the produced filter 100. For example, a smaller volume can facilitate the arrangement in various application environments, such that it has an extremely high practical value and can be widely applied.

The above description is merely preferable embodiments of the present disclosure, and is not intended to limit the present disclosure, and for a person skilled in the art, the present disclosure may be modified and changed in various ways. Any modifications, equivalent substitutions, and improvements made within the spirit and the principle of the present disclosure shall all be covered in the scope of protection of the present disclosure.

1. A filter production method, wherein the method comprises steps of:
providing a substrate structure;
producing and forming a line structure on at least one side of the substrate structure, wherein the line structure comprises at least one line layer, and at least one of the line layers has at least one inductor element; and
producing and forming a capacitor structure and/or a resonator structure on the side of the at least one line layer close to the substrate structure and/or away from the substrate structure, wherein the capacitor structure comprises at least one capacitor element, and the resonator structure comprises at least one acoustic resonator;
wherein the substrate structure and the line structure as well as the capacitor structure and/or the resonator structure form a lamellar stack structure, and the inductor element and the capacitor element and/or the acoustic resonator are in electrical connection with each other, so as to form a filter circuit.

2. The filter production method according to claim 1, wherein the step of producing and forming a capacitor structure and/or a resonator structure on the side of the at least one line layer close to the substrate structure and/or away from the substrate structure comprises:
producing and forming at least one capacitor element and/or at least one acoustic resonator on the basis of at least one external surface of the substrate structure.

3. The filter production method according to claim 1, wherein the step of producing and forming a capacitor structure and/or a resonator structure on the side of the at least one line layer close to the substrate structure and/or away from the substrate structure comprises:
producing and forming at least one capacitor element and/or at least one acoustic resonator in at least one inwardly concave area of the substrate structure.

4. The filter production method according to claim 3, wherein the step of producing and forming at least one capacitor element and/or at least one acoustic resonator in at least one inwardly concave area of the substrate structure comprises:
producing and forming at least one inwardly concave area on at least one external surface of the substrate structure;
producing and forming a substrate layer on the basis of the external surface of the substrate structure in each of the inwardly concave areas; and
producing and forming at least one capacitor element and/or at least one acoustic resonator on the basis of the surface on each of the substrate layers not contacting with the substrate structure.

5. The filter production method according to claim 4, wherein the step of producing and forming a substrate layer on the basis of the external surface of the substrate structure comprises:
producing a substrate layer of a material differing from that of the substrate structure on the basis of the external surface of the substrate structure, wherein the substrate layer is configured for producing and forming an acoustic resonator.

6. The filter production method according to claim 1, wherein the step of producing and forming a capacitor structure or a resonator structure on the side of the at least one layer of the inductor element close to the substrate structure and/or away from the substrate structure comprises:
producing and forming, after the production and formation of one line layers, at least one capacitor element and/or at least one acoustic resonator on the basis of a dielectric isolation layer formed on the line layer.

7. The filter production method according to claim 1, wherein the step of producing and forming a line structure on at least one side of the substrate structure comprises:
producing and forming, after the production and formation of a layer of a lamellar structure having a capacitor element and/or an acoustic resonator, a line layer on the basis of a dielectric isolation layer formed on the lamellar structure.

8. The filter production method according to claim 1, wherein the step of producing and forming a line structure on at least one side of the substrate structure comprises:
producing and forming at least one line layer on the basis of at least one external surface of the substrate structure.

9. The filter production method according to claim 8, wherein the step of producing and forming at least one line layer on the basis of at least one external surface of the substrate structure comprises:
performing a window etching operation on a metal foil on the substrate structure;
performing a drilling operation on the basis of the surface of the window-etched metal foil away from the substrate structure, so as to form a connecting via hole penetrating the metal foil and the substrate structure;
performing a metal electroplating operation on the basis of the surface of the drilled metal foil away from the substrate structure, so as to form a metal layer covering the metal foil and filling the connecting via hole; and
performing a graphics etching operation on the surface of the metal layer away from the metal foil to form a line layer.

10. A filter, wherein the filter is produced and formed on the basis of the filter production method according to claim 1.
